(19) United States
(12) Patent Application Publication
(10) Pub. No.: US 2021/0408783 A1
(43) Pub. Date: Dec. 30, 2021

(54) EARTHING MODULE

(71) Applicant: ABB Schweiz AG, Baden (CH)

(72) Inventors: Dietmar Gentsch, Ratingen (DE); Christian Reuber, Willich (DE)

(21) Appl. No.: 17/471,177

(22) Filed: Sep. 10, 2021

Related U.S. Application Data
(63) Continuation of application No. PCT/EP2020/054208, filed on Feb. 18, 2020.

(30) Foreign Application Priority Data
Mar. 12, 2019 (EP) 19162182.0

(51) Int. Cl. H02H 7/22; H02H 1/00; G01R 31/52

(52) U.S. Cl. CPC H02H 7/222; G01R 31/52; H02H 1/0015

(57) ABSTRACT

A short circuit current detection device for a medium voltage or high voltage switchgear includes: a reed contact; and a holder for holding the reed contact, the holder being mountable with a defined orientation to a conductor of the switchgear. At a location where the holder is mounted, the conductor has a longitudinal axis. The conductor enables a current to flow through the conductor in a direction of the longitudinal axis. The holder positions the reed contact with respect to the longitudinal axis such that when a magnitude of the current flow through the conductor exceeds a threshold current value the reed contact closes.

### CROSS-REFERENCE TO PRIOR APPLICATION

This application is a continuation of International Patent Application No. PCT/EP2020/054208, filed on Feb. 18, 2020, which claims priority to European Patent Application No. EP 19162182.0, filed on Mar. 12, 2019. The entire disclosure of both applications is hereby incorporated by reference herein.

### FIELD

The present invention relates to a short circuit current detection device for a medium or high voltage switchgear, such as an air-insulated switchgear or a gas-insulated switchgear, to an earthing module for a medium or high voltage switchgear, and to a switchgear having such a short circuit detection device and/or earthing module.

### BACKGROUND

For the limitation of the effects of a fault arc inside a switchgear panel, it is desirable to quickly establish a stable current path from the conductor to ground, so that the fault arc is short-circuited and so quenched. To address this fast earthing systems are used. These use stored energy, for example from springs or micro gas generators, and are triggered by a control device depending on for example the magnitude of the current, the rate of rise of the current and/or the light emitted by the fault arc. The accurate measurement of the current is complex and expensive. The control device or module can therefore be expensive, and these systems are powered by auxiliary energy, which can impact the availability of the system. This further impacts the assembly of the switchgear panel due to the necessary wiring and increases costs.

There is a need to address this issue.

### SUMMARY

In an embodiment, the present invention provides a short circuit current detection device for a medium voltage or high voltage switchgear, the short circuit detection device comprising: a reed contact; and a holder configured to hold the reed contact and to be mounted with a defined orientation to a conductor of the switchgear, wherein, at a location where the holder is mounted, the conductor has a longitudinal axis, the conductor being configured to enable a current to flow through the conductor in a direction of the longitudinal axis, and wherein the holder is configured to position the reed contact with respect to the longitudinal axis such that when a magnitude of the current flow through the conductor exceeds a threshold current value the reed contact is configured to close.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 shows an example of a reed contact positioned relative to a conductor through which current is flowing;

FIG. 2 shows an example of a reed contact in different configurations relative to a conductor through which current is flowing;

FIG. 3 shows an example of a holder for a reed contact mounted to a conductor through which current is flowing;

FIG. 4 shows an example of a holder for a reed contact mounted to the surrounding structure of a switchgear so that it is oriented to a conductor through which current is flowing;

FIG. 5 shows an example of an earthing module; and

FIG. 6 shows examples of closing thresholds of an exemplar reed contact with respect to different positions relative to a conductor through which current is flowing.

### DETAILED DESCRIPTION

In an embodiment, the present invention provides an improved ability to detect short circuit currents caused for example by a fault arc and to limit the effects of a fault arc in a switchgear panel, hereafter referred to as switchgear.

In a first aspect, there is provided a short circuit current detection device for a medium voltage or high voltage switchgear, the short circuit detection device comprising:

a reed contact; and

a holder.

The holder is configured to hold the reed contact. The holder is configured to be mounted with a defined orientation to a conductor of a switchgear. At a location where the holder is mounted the conductor has a longitudinal axis. The conductor is configured to enable a current to flow through the conductor in a direction of the longitudinal axis. The holder is configured to position the reed contact with respect to the longitudinal axis, such that when a magnitude of the current flow through the conductor exceeds a threshold current value the reed contact is configured to close.

In an example, the threshold current value at which the reed contact is configured to close is based at least in part on an intrinsic sensitivity of the reed contact.

In an example, the threshold current value at which the reed contact is configured to close is based at least in part on a magnitude of a distance perpendicular to the longitudinal axis at which the reed contact is positioned.

In an example, the reed contact has a center axis. The threshold current value at which the reed contact is configured to close is based at least in part on a magnitude of at least one angle between the longitudinal axis and the center axis.

In an example, an angle of the at least one angle is measured in a direction of an axis perpendicular to the longitudinal axis.

In an example, the threshold current value at which the reed contact is configured to close is configured to increase as the magnitude of the angle increases from an orientation perpendicular to the axis perpendicular to the longitudinal axis.

In an example, an angle of the at least one angle is measured in a direction of an axis parallel to the longitudinal axis.

In an example, the threshold current value at which the reed contact is configured to close is configured to increase as the magnitude of the angle increases from an orientation perpendicular to the axis parallel to the longitudinal axis.

In an example, the short circuit detection device comprises a ferromagnetic shield. The threshold current value at which the reed contact is configured to close is based at least in part on whether the ferromagnetic shield is positioned between the reed contact and the conductor.

In an example, the threshold current value at which the reed contact is configured to close is based at least in part on at least one characteristic of the ferromagnetic shield.

In an example, the at least one characteristic of the ferromagnetic shield comprises one or more of: thickness, width, length, material.

In an example, the holder comprises a plurality of holes configured to enable the reed contact to be held at a plurality of distances from the longitudinal axis.

In an example, the reed contact has a center axis, and wherein the holder comprises a plurality of holes configured to enable the center axis of the reed contact to be held at a plurality of angles with respect to the longitudinal axis.

In an example, the holder comprises a plurality of slots configured to enable the optional insertion of a ferromagnetic shield between the conductor and the provided holes for holding the reed contact.

In an example, the holder comprises means of fixation directly to the conductor so that the holder can be fixed with a defined orientation to the conductor.

In an example, the holder comprises means of fixation to the surrounding structure of the switchgear so that the holder can be fixed to the switchgear with a defined orientation to the conductor.

In a second aspect, there is provided an earthing module for a medium voltage or high voltage switchgear, the earthing module comprising:

a short circuit detection device according to the first aspect;

a photovoltaic cell; and

a trigger unit of a fast earthing switch.

The photovoltaic cell is configured to generate the electrical energy required to activate the trigger unit on the basis of radiation from an arc event associated with a conductor of a medium voltage or high voltage switchgear. The reed contact within the short circuit detection circuit is configured to close when a magnitude of the current through the conductor associated with the arc event exceeds the threshold current value. Closure of the reed contact within the short circuit detection circuit is configured to close a circuit such that the photovoltaic cell is configured to activate the trigger unit.

In an example, the trigger unit comprises a micro gas generator or spring system. Activation of the trigger unit is configured to release gas or activate a spring to move a connector to make an electrical connection between the conductor and earth potential.

In an example, the earthing module comprises three short circuit detection devices each associated with a different one of three conductors of a three phase system. One or more of three reed contacts within one or more of the three short circuit detection circuits is configured to close when a magnitude of the current through one or more of the three conductors associated with the arc event exceeds the threshold current value. Activation of the trigger unit is configured to release gas or activate one or more springs to move one or more of three connectors to make an electrical connection between one or more of the three conductors and earth potential.

In an example, activation of the trigger unit is configured to release gas or activate springs to move the three connectors to make an electrical connection between the three conductors and earth potential.

In a third aspect, there is provided a switchgear comprising one or more short circuit detection devices according to the first aspect.

In a fourth aspect, there is provided a switchgear comprising one or more earthing modules according to the second aspect.

The above aspects and examples will become apparent from and be elucidated with reference to the embodiments described hereinafter.

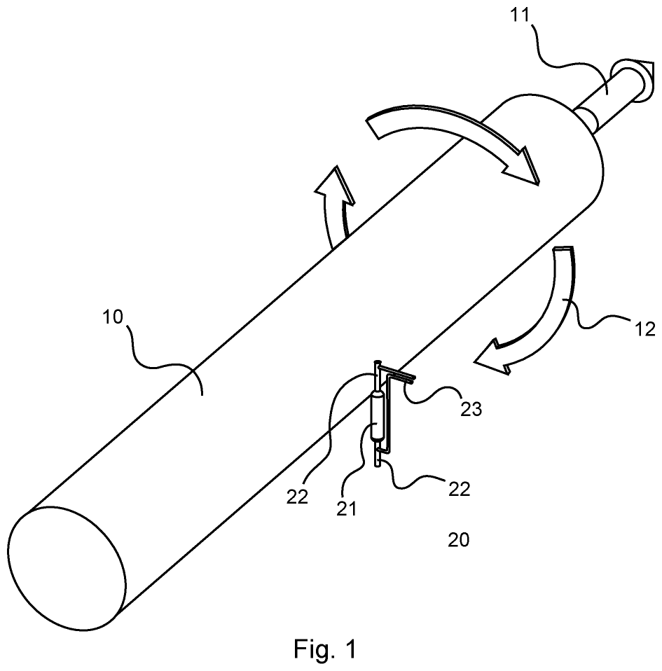

FIGS. 1-6 relate to a short circuit detection device and associated earthing module for a switchgear, such as a medium or high voltage switchgear. In an example a short circuit current detection device comprises a reed contact 20, and a holder 100. The holder is configured to hold the reed contact. The holder is configured to be mounted with a defined orientation to a conductor of a switchgear. At a location where the holder is mounted the conductor has a longitudinal axis. The conductor is configured to enable a current to flow through the conductor in a direction of the longitudinal axis. The holder is configured to position the reed contact with respect to the longitudinal axis, such that when a magnitude of the current flow through the conductor exceeds a threshold current value the reed contact is configured to close.

According to an example, the threshold current value at which the reed contact is configured to close is based at least in part on an intrinsic sensitivity of the reed contact.

According to an example, the threshold current value at which the reed contact is configured to close is based at least in part on a magnitude of a distance perpendicular to the longitudinal axis at which the reed contact is positioned.

According to an example, the reed contact has a center axis. The threshold current value at which the reed contact is configured to close is based at least in part on a magnitude of at least one angle between the longitudinal axis and the center axis.

According to an example, an angle of the at least one angle is measured in a direction of an axis perpendicular to the longitudinal axis.

According to an example, the threshold current value at which the reed contact is configured to close is configured to increase as the magnitude of the angle increases from an orientation perpendicular to the axis perpendicular to the longitudinal axis.

According to an example, an angle of the at least one angle is measured in a direction of an axis parallel to the longitudinal axis.

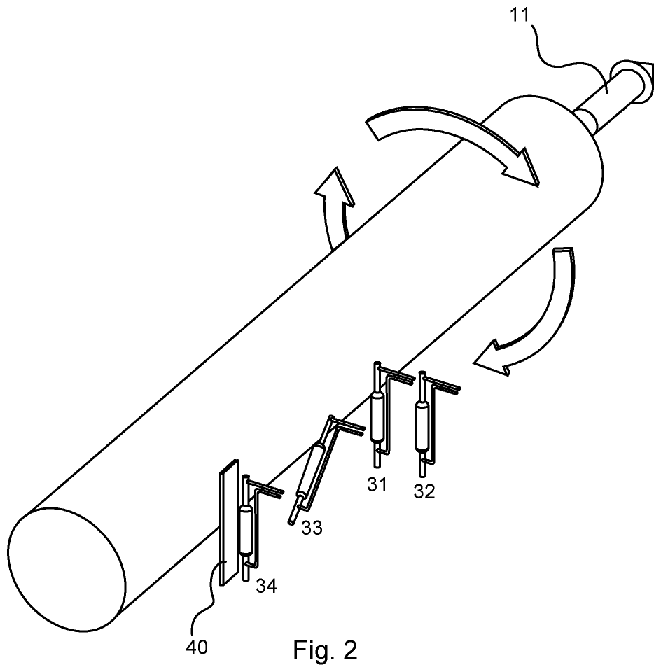

In other words, looking for example at FIG. 1 the arrow 11 shows current flow along the longitudinal axis of the conductor 10. An axis then extends perpendicular to the longitudinal axis along which current flows and extends through the reed contact 20. In FIG. 1 the center axis of the reed contact 20 is itself perpendicular to the axis that extends perpendicular to the longitudinal axis of the conductor. The arrows around the conductor represent the magnetic flux lines, and in FIG. 1 the reed contact center axis is shown at an orientation perpendicular to the magnetic flux. The sensitivity of the reed contact is then maximised. However, as shown in FIG. 2 the reed contact can be angled in a direction of an axis that is parallel to the longitudinal axis of the conductor and in this way the sensitivity of the reed contact is reduced, and the threshold current at which it closes increases. However, the reed contact can also be angled in the other direction, in the direction of the magnetic flux arrows, in the direction of the axis perpendicular to the longitudinal axis, and again the reed contact sensitivity is decreased and the threshold current at which it closes increases.

According to an example, the threshold current value at which the reed contact is configured to close is configured to increase as the magnitude of the angle increases from an orientation perpendicular to the axis parallel to the longitudinal axis.

According to an example, the short circuit detection device comprises a ferromagnetic shield 40. The threshold current value at which the reed contact is configured to close is based at least in part on whether the ferromagnetic shield is positioned between the reed contact and the conductor.

According to an example, the threshold current value at which the reed contact is configured to close is based at least in part on at least one characteristic of the ferromagnetic shield.

According to an example, the at least one characteristic of the ferromagnetic shield comprises one or more of: thickness, width, length, material.

According to an example, the holder comprises a plurality of holes configured to enable the reed contact to be held at a plurality of distances from the longitudinal axis.

According to an example, the reed contact has a center axis, and wherein the holder comprises a plurality of holes configured to enable the center axis of the reed contact to be held at a plurality of angles with respect to the longitudinal axis.

According to an example, the holder comprises a plurality of slots configured to enable the optional insertion of a ferromagnetic shield between the conductor and the provided holes for holding the reed contact.

According to an example, the holder comprises means of fixation directly to the conductor so that the holder can be fixed with a defined orientation to the conductor.

According to an example, the holder comprises means of fixation to the surrounding structure of the switchgear so that the holder can be fixed to the switchgear with a defined orientation to the conductor.

In an example an earthing module for a medium voltage or high voltage switchgear comprises a short circuit detection device as described above and a photovoltaic cell 200. The earthing module also comprises a trigger unit of a fast earthing switch 210. The photovoltaic cell is configured to generate the electrical energy required to activate the trigger unit on the basis of radiation from an arc event associated with a conductor of a medium voltage or high voltage switchgear. The reed contact 20, 220, 230, 240 within the short circuit detection circuit is configured to close when a magnitude of the current through the conductor associated with the arc event exceeds the threshold current value. Closure of the reed contact within the short circuit detection circuit is configured to close a circuit 250 such that the photovoltaic cell is configured to activate the trigger unit.

According to an example, the trigger unit comprises a micro gas generator or a spring system. Activation of the trigger unit is configured to release gas or activate a spring to move a connector to make an electrical connection between the conductor and earth potential.

According to an example, the earthing module comprises three short circuit detection devices each associated with a different one of three conductors of a three phase system. One or more of the three reed contacts 220, 230, 240 within one or more of the three short circuit detection circuits is configured to close when a magnitude of the current through one or more of the three conductors associated with the arc event exceeds the threshold current value. Activation of the trigger unit is configured to release gas or activate one or more springs to move one or more of three connectors to make an electrical connection between one or more of the three conductors and earth potential.

According to an example, activation of the trigger unit is configured to release gas or activate springs to move the three connectors to make an electrical connection between the three conductors and earth potential.

As discussed above, a switchgear can have one or more of the above described short circuit detection devices and/or one or more of the above described earthing modules.

Thus, reed contacts in the vicinity of the primary conductors are used to detect a current having a higher value than a pre-defined triggering value. Used in combination with a photovoltaic cell, that detects the light of the internal arc and generates the energy for releasing a protective device, a very simple arc protection system can be realised that does not require auxiliary power.

Continuing with the figures, several embodiments are now described in detail.

FIG. 1 shows a current that may run through the conductor 10 with the direction 11. The current is generating a magnetic field around the conductor in the direction indicated by the arrows 12. A reed contact 20 basically consists of a glass envelope 21, where an electrical contact is located, and two terminals 22. Two wires 23 can be added, for example by soldering, for the secondary connection of the reed contact. The reed contact is sensitive to magnetic fields in its longitudinal direction, therefore the orientation shown in FIG. 1 is the most sensitive with respect to current flowing in the conductor 10.

When the current reaches a certain threshold, it will generate a corresponding magnetic field, and the reed contact will therefore close. This can be evaluated for further actions, for example for releasing an earthing switch.

For the adjustment of the current threshold, four independent methods can be utilised, that can also be combined:

### Intrinsic Sensitivity of the Reed Contact

Reed contacts are available off the shelf with a wide range of sensitivities, but also with a relatively small sensitivity tolerance for a certain type. For a certain application, a suitable type of reed contact can therefore be selected.

### Distance of the Reed Contact to the Conductor

The strength of the magnetic field decreases with increasing distance to the center of the conductor. Therefore, the current threshold can be adjusted by selection of the distance of the reed contact to the center of the conductor, as shown in FIG. 2. The sensor at location 32 results in a higher current threshold than the sensor at the location 31, i.e. more current is required to generate a magnetic field that is suitable for operating the reed contact at the location 32 compared to a sensor at the location 31.

### Angle of the Reed Contact to the Magnetic Field

Location 33 in FIG. 2 shows a rotation of the reed contact. This turns the magnetically sensitive axis of the contact away from the main direction of the magnetic field, so that the current threshold will be increased, i.e. more current is required to generate a magnetic field that is suitable for operating the reed contact at the location 33 compared to a reed contact at the location 31.

### Usage of Ferromagnetic Shields

FIG. 2 further shows a ferromagnetic shield 40. Ferromagnetic parts attract magnetic fields from their non-ferromagnetic vicinity, so that the presence and dimensions of 40 increases the current threshold of the corresponding reed contact at position 34, i.e. with a shield 40, more current is required to generate a magnetic field that is suitable for operating the reed contact behind the shield 40 compared to the situation without the shield 40.

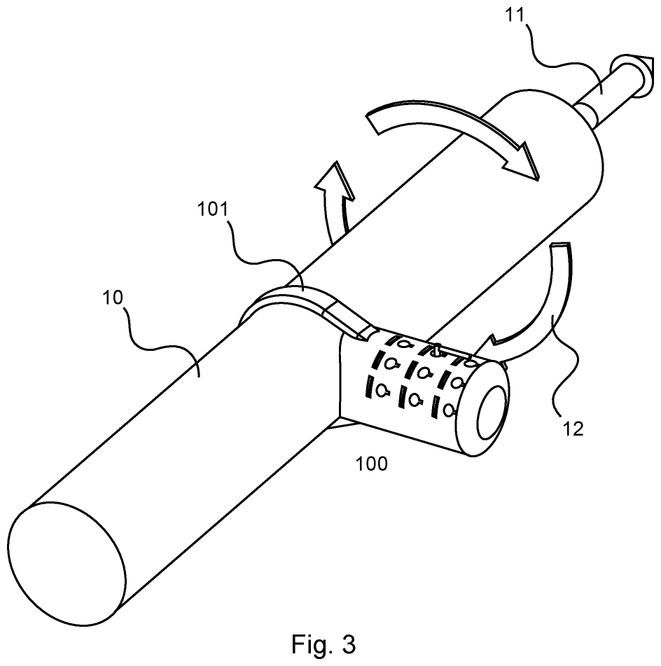

FIG. 3 shows a realisation of the discussed options, where a reed contact holder 100 is utilized. FIG. 3 shows the contact holder 100 that provides options to host a reed contact at different distances to the conductor, and at different angles, and with the option to insert a ferromagnetic shield. The holder 100 can for example be made from thermoplastic material or from epoxy. After insertion of the reed contact and optionally the shield, the remaining openings can be closed with self-locking plugs, having for example a snap fit, to avoid the reed contact or the shield moving or vibrating or falling out. Optionally, the reed contact and the shield can be fixed with glue.

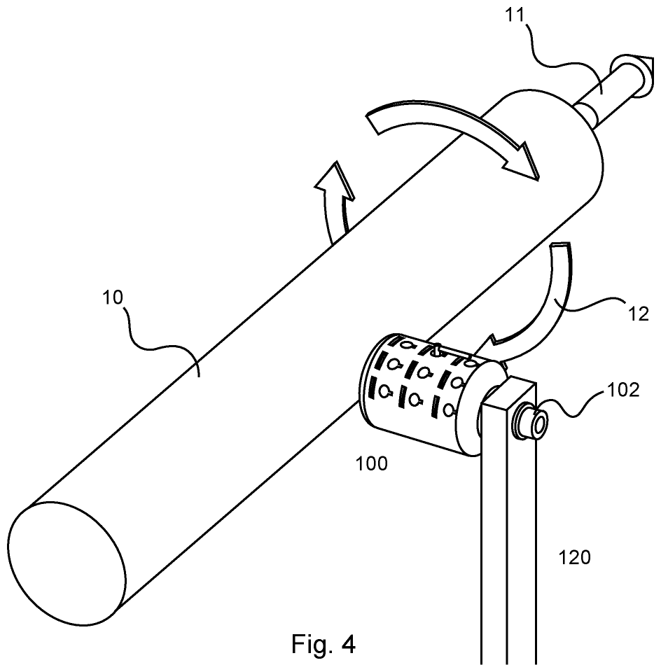

In case the conductor 100 has an earthed layer, the holder 100 can directly be fixed to the conductor, for example using a clamp 101, as shown in FIG. 3. If the conductor 100 is not insulated, or if an additional creepage path shall be avoided, the holder 100 can be fixed to a supporting structure 120 in the vicinity of the conductor, for example using a screw fixation 102, as shown in FIG. 4. The supporting structure 120 can also be the wall of a gas insulated switchgear GIS compartment.

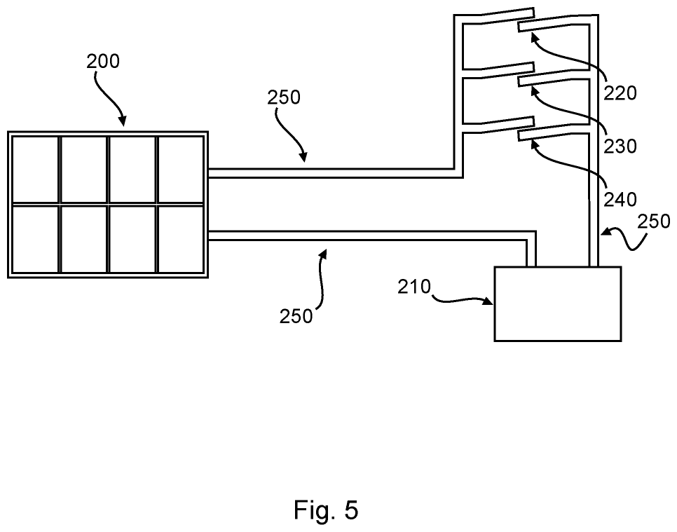

In combination with a stored energy fast earthing switch for internal arc protection and a photovoltaic cell, reed contacts offer a simple way of triggering the earthing switch without the need for auxiliary energy. FIG. 5 shows this in principle. In the situation where an internal arc fault occurs, the light of the arc will generate the required energy in the photovoltaic cell 200. At the same time one of the three currents of a three phase system is above the adjusted triggering value, the electrical circuit 250 is closed by one or more reed contacts 220, 230, 240 that are connected in parallel, and the electrical energy can arrive at the trip unit 210 of the stored energy fast earthing switch. The trip unit 210 can for example be a micro gas generator.

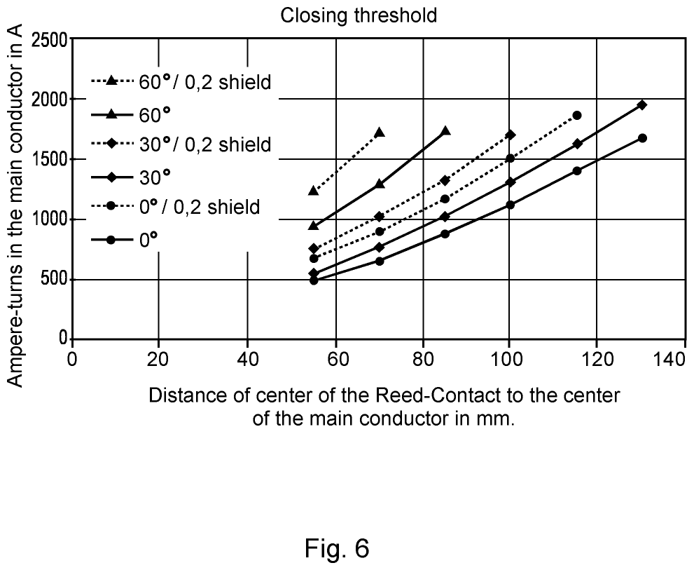

FIG. 6 shows the closing threshold of a reed contact, with and without a ferromagnetic shield, at different angles to the longitudinal axis of a conductor, as a function of lateral distance from the longitudinal axis of the conductor. This indicates how a reed contact can be positioned with respect to a conductor in order to provide a required threshold trigger level as required.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### REFERENCE NUMERALS

10 Conductor
11 Direction of current flowing through 10
12 Direction of magnetic field due to 11
20 Reed contact
21 Glass envelope of 20
22 Terminals of 20
23 Connection wire of 20
31 First position of reed contact
32 Second position of reed contact
33 Third position of reed contact
34 Fourth position of reed contact
40 Ferromagnetic shield
100 Reed contact holder
101 Clamp fixation
102 Screw fixation
120 Supporting structure
200 Photovoltaic cell
210 Triggering unit of fast earthing switch
220 Reed contact of first phase
230 Reed contact of second phase
240 Reed contact of third phase
250 Electrical circuit

What is claimed is:

1. A short circuit current detection device for a medium voltage or high voltage switchgear, the short circuit detection device comprising:
a reed contact; and
a holder configured to hold the reed contact and to be mounted with a defined orientation to a conductor of the switchgear,
wherein, at a location where the holder is mounted, the conductor has a longitudinal axis, the conductor being configured to enable a current to flow through the conductor in a direction of the longitudinal axis, and
wherein the holder is configured to position the reed contact with respect to the longitudinal axis such that when a magnitude of the current flow through the conductor exceeds a threshold current value the reed contact is configured to close.

2. The short circuit current detection device of claim 1, wherein the threshold current value at which the reed contact is configured to close is based at least in part on an intrinsic sensitivity of the reed contact.

3. The short circuit current detection device of claim 1, wherein the threshold current value at which the reed contact is configured to close is based at least in part on a magnitude of a distance perpendicular to the longitudinal axis at which the reed contact is positioned.

4. The short circuit current detection device of claim 1, wherein the reed contact has a center axis, and
wherein the threshold current value at which the reed contact is configured to close is based at least in part on a magnitude of at least one angle between the longitudinal axis and the center axis.

5. The short circuit current detection device of claim 4, wherein an angle of the at least one angle is measured in a direction of an axis perpendicular to the longitudinal axis.

6. The short circuit current detection device of claim 5, wherein the threshold current value at which the reed contact is configured to close is configured to increase as the magnitude of the angle increases from an orientation perpendicular to the axis perpendicular to the longitudinal axis.

7. The short circuit detection device of claim 4, wherein an angle of the at least one angle is measured in a direction of an axis parallel to the longitudinal axis.

8. The short circuit detection device of claim 7, wherein the threshold current value at which the reed contact is configured to close is configured to increase as the magnitude of the angle increases from an orientation perpendicular to the axis parallel to the longitudinal axis.

9. The short circuit detection device of claim 1, further comprising:
a ferromagnetic shield,
wherein the threshold current value at which the reed contact is configured to close is based at least in part on whether the ferromagnetic shield is positioned between the reed contact and the conductor.

10. The short circuit detection device of claim 9, wherein the threshold current value at which the reed contact is configured to close is based at least in part on at least one characteristic of the ferromagnetic shield.

11. The short circuit detection device of claim 10, wherein the at least one characteristic of the ferromagnetic shield comprises one or more of: thickness, width, length, material.

12. The short circuit detection device of claim 1, wherein the holder comprises a plurality of holes configured to enable the reed contact to be held at a plurality of distances from the longitudinal axis.

13. The short circuit detection device of claim 1, wherein the reed contact has a center axis, and
wherein the holder comprises a plurality of holes configured to enable the center axis of the reed contact to be held at a plurality of angles with respect to the longitudinal axis.

14. The short circuit detection device of claim 13, wherein the holder comprises a plurality of slots configured to enable insertion of a ferromagnetic shield between the conductor and the provided holes for holding the reed contact.

15. The short circuit detection device of claim 1, wherein the holder is configured to be fixed directly to the conductor so that the holder is fixable with a defined orientation to the conductor.

16. The short circuit detection device of claim 1, wherein the holder is configured to be fixed at a surrounding structure of the switchgear so that the holder is fixable with a defined orientation to the conductor.

17. An earthing module for a medium voltage or high voltage switchgear, the earthing module comprising:
at least one short circuit detection device of claim 1;
a photovoltaic cell; and
a trigger unit of a fast earthing switch,
wherein the photovoltaic cell is configured to generate an electrical energy required to activate the trigger unit based on radiation from an arc event associated with the conductor of the medium voltage or high voltage switchgear,
wherein the reed contact within the short circuit detection circuit is configured to close when a magnitude of the current through the conductor associated with the arc event exceeds the threshold current value, and
wherein closure of the reed contact within the short circuit detection circuit is configured to close a circuit such that the photovoltaic cell is configured to activate the trigger unit.

18. The earthing module of claim 17, wherein the trigger unit comprises a micro gas generator or spring system, and
wherein activation of the trigger unit is configured to release gas or activate a spring to move a connector to make an electrical connection between the conductor and earth potential.

19. The earthing module of claim 18, wherein the at least one short circuit detection device comprises three short circuit detection devices, each associated with a different one of three conductors of a three phase system,
wherein one or more of three reed contacts within one or more of the three short circuit detection circuits is configured to close when a magnitude of the current through one or more of the three conductors associated with the arc event exceeds the threshold current value, and
wherein activation of the trigger unit is configured to release gas or activate one or more springs to move one or more of three connectors to make an electrical connection between one or more of the three conductors and earth potential.

20. The earthing module of claim 19, wherein activation of the trigger unit is configured to release gas or activate springs to move the three connectors to make an electrical connection between the three conductors and earth potential.

21. A switchgear, comprising:
one or more short circuit detection devices of claim 1.

22. A switchgear, comprising:
one or more earthing modules of claim 17.
